(19) United States
(12) Patent Application Publication
(10) Pub. No.: US 2010/0186813 A1
(43) Pub. Date: Jul. 29, 2010

(54) Photovoltaic module

(75) Inventors: Hartmut Knoll, Bitterfeld (DE); Peter Lechner, Vaterstetten (DE); Roland Weidl, Bollberg (DE); Erwin Heckel, Au in der Hallertau (DE); Ralf Gueldner, Aschaffenburg (DE)

Correspondence Address: FLYNN THIEL BOUTELL & TANIS, P.C., 2026 RAMBLING ROAD, KALAMAZOO, MI, 49008-1631, US

(73) Assignee: SCHOTT Solar AG, Mainz (DE)

(21) Appl. No.: 12/657,864

(22) Filed: Jan. 28, 2010

(30) Foreign Application Priority Data
Jan. 29, 2009 (DE) 10 2009 006 720.5
Feb. 24, 2009 (DE) 10 2009 010 262.0
Sep. 2, 2009 (DE) 10 2009 039 750.7

(51) Int. Cl. H01L 31/00; B23K 1/00; B23K 31/02; B23K 1/002

(52) U.S. Cl. 136/256; 228/101; 228/176; 219/616

(57) ABSTRACT

For fastening the contact strip (8) to the back electrode layer (4) of a photovoltaic module, the back electrode layer (4) is provided on its outer side with a tin-, copper- and/or silver-containing contact layer (12). Subsequently the contact strip (8) provided with solder (17) on the joining surface is connected to the back electrode layer (4) by soldering. The contact layer (12) causes good adhesion of the back surface encapsulation material (13) to be obtained. A barrier layer (11) prevents alloying of the tin-solder with the layers (9, 10) of the back electrode layer (4).

This invention relates to a photovoltaic module according to the preamble of claim 1 and to a method for fastening the contact strips to such a module.

To permit the charge carriers generated by light irradiation to be collected and their energy utilized, contact strips are fastened to the back electrode layer of individual cells of the photovoltaic module. Contacting of the contact strips with the back electrode layer can be carried out in different ways, for example by bonding, soldering or welding. Soldering is preferred to bonding because it not only leads to a more stable mechanical and electrical connection, but is also substantially simpler in terms of process engineering.

When the contact strips are to be fastened to the back electrode layer by a soldered connection, the joining surface, i.e. terminating surface, of the back electrode layer must consist of a solderable material. For this purpose, known photovoltaic modules usually have a nickel-vanadium layer on the back electrode layer.

Although a soldered connection can then be produced with lead-containing solders, the process window is very small, so that even small variations in the process flow, for example temperature deviations or small deviations in the thickness of the solder layer, can lead to faulty soldering points and thus to faulty modules, in particular with thin-film solar modules. Upon use of unleaded solder, the soldering process is far more poorly controllable, so that faulty modules result nearly without exception.

In view of the REACH Regulation and other legal provisions for protecting health and the environment which have banished lead from photovoltaic modules, however, the use of unleaded solders is of especially great interest in the production of photovoltaic modules.

The object of the invention is to provide a solder connection between the back electrode layer and the contact strips of a photovoltaic module which can be produced faultlessly both with unleaded and with lead-containing solder with a process window that is not too narrow.

This is attained according to the invention with the photovoltaic module according to claim 1 and the method according to claim 17. The subclaims state advantageous embodiments of the invention.

According to the invention, the back electrode layer is provided on its outer side, i.e. its rear side facing away from the light incidence side of the photovoltaic module, with a thin tin-, copper- and/or silver-containing contact layer. The layer thickness of the contact layer is normally at most 500 nm and preferably at least 1 nm. Particularly preferable is a layer thickness of the contact layer of at least 10 nm and at most 100 nm, in particular of 15 to 50 nm.

The contact strip can then be fastened to the thus pretreated tin-, copper- and/or silver-containing contact layer by soldering. For this purpose, the contact strip is provided with a solder at least on its joining surface facing the back electrode layer, thereby producing upon soldering a soldered connection between the contact strip and the back electrode layer.

The tin-, copper- and/or silver-containing contact layer can consist of (unalloyed) tin, copper or silver or of a tin alloy, copper alloy or silver alloy. Because in particular tin or tin alloys readily oxidize in air at least on the surface, the tin-containing layer can also be present in an at least partly oxidized form. The tin content of the tin-containing layer is preferably at least 10 wt. %, in particular more than 50 wt. %. In the same manner, the copper content or silver content of the copper- or silver-containing contact layer is preferably at least 10 wt. %, in particular more than 50 wt. % copper or silver. The copper alloy and silver alloy can likewise be oxidized at least partly. The same applies to pure copper and optionally also to pure silver.

The tin-, copper- and/or silver-containing layer is preferably applied by a PVD process, i.e. physical gas phase deposition, in particular by magnetron sputtering. In so doing, the tin or tin alloy can be sputtered reactively with oxygen as tin oxide (SnOₓ).

The back electrode layer has one or more layers consisting of metal, for example aluminum, silver, copper and/or chromium. The tin-, copper- and/or silver-containing contact layer is then applied to the layer terminating the layer structure of the back electrode layer on the side of the solar cell facing away from the semiconductor layer. Thus, the layer terminating the layer structure of the back electrode layer can be for example a protective layer consisting of a nickel-vanadium alloy or tellurium.

The inventive contact layer permits the back electrode layer to be very well soldered. That is, the contact layer facilitates the wettability and thus the solderability of the back electrode layer, both with lead-containing and with unleaded solder. This leads to a more stable and less fault-prone soldering process. That is, the better wettability of the back electrode layer means that less energy has to be supplied for soldering, thereby permitting the soldering temperature and/or soldering time to be lowered. The shorter soldering times in addition permit the process time to be reduced. The invention also permits a flawless soldered connection to be produced with unleaded solder. Further, the process becomes better controllable upon use of lead-containing solder.

The contact strip normally has a width of 1 to 5 mm and a thickness of 20 to 500 μm, in particular 50 to 200 μm. It usually consists of metal, in particular copper, aluminum or silver, or of an alloy of said metals, optionally also of steel.

The contact strip is provided with a solder layer at least on the joining surface facing the back electrode layer. However, the contact strip is normally coated with solder on the total circumference. The thickness of the solder layer can be 5 to 50 μm, in particular 10 to 30 μm. The contact strip provided with the solder layer can be produced by a hot dipping process by which the contact strip is guided continuously through the molten solder.

The solder can be a lead-containing or an unleaded soft solder. The lead-containing solder can consist for example of lead-containing tin-solder, i.e. of a lead-containing tin alloy, and the unleaded tin-solder can be an unleaded tin alloy, in particular an alloy from the group consisting of tin/silver, tin/copper or tin/silver/copper.

According to the invention, any common soldering method can be used for connecting the contact strip to the back electrode layer. That is, it is possible to carry out for example thermal soldering by contact with a medium of high temperature, ultrasonic soldering or laser soldering. However, it is particularly preferable to apply an inductive soldering method by which the contact strip is energized, in particular high-frequency induction soldering.

The photovoltaic module can be constructed of thin-film solar cells or crystalline solar cells based on a semiconductor wafer.

The thin-film solar cells have on the light incidence side of the module a transparent, electrically non-conductive substrate, for example a glass plate, on which a front electrode layer, at least one semiconductor layer and the back electrode layer are successively disposed. The single cells of the photovoltaic module are normally series-connected. For this purpose, the front electrode layer, the semiconductor layer and the back electrode layer are patterned by separating lines. The contact strip is then soldered to the single cell intended for current collection.

The front electrode layer of the inventive photovoltaic thin-film module has a thickness of e.g. 50 to 100 nm and preferably consists of a transparent, electrically conductive metal oxide, in particular zinc oxide or tin oxide, for example aluminum-doped zinc oxide, indium tin oxide or e.g. fluorine-doped tin oxide. The semiconductor layer can consist of amorphous, micromorphous or microcrystalline silicon. However, it can also be a composite semiconductor layer, for example a II-VI semiconductor such as cadmium telluride, a III-V semiconductor such as gallium arsenide or a I-III-VI semiconductor such as copper indium diselenide.

The back electrode layer of the thin-film solar cells of the inventive module has an interlayer consisting of a transparent electrically conductive metal oxide, in particular zinc oxide, on the side facing the semiconductor layer, preferably as a diffusion barrier and for improving the reflecting properties. However, other transparent metal oxides can also be used, for example tin oxide or indium tin oxide.

The back electrode layer which comprises the reflector layer has a layer thickness of 100 to 500 nm, in particular 200 to 300 nm. The metallic reflector layer can consist for example of aluminum, silver, copper and/or chromium or an alloy of said metals. Also, it can be constructed from a plurality of sublayers consisting of different materials, for example, a first layer consisting of silver facing the semiconductor layer, and an aluminum layer applied thereto as the second layer to form the reflector layer for reflecting the light incident on the back electrode layer and not absorbed by the semiconductor layer. The thickness of the reflector layer can be 50 to 300 nm.

In solar modules for example based on amorphous, micromorphous or microcrystalline silicon or cadmium telluride, but also a crystalline wafer, there is laminated on the back electrode layer for back surface encapsulation for example an EVA embedding foil with a glass plate (so-called glass/glass laminate) or with at least one further foil (so-called glass/foil laminate). In so doing, the embedding foil is laminated directly on the back electrode layer previously provided with the contact strips by bonding or soldering.

However, the embedding foils, in particular an EVA foil, often has unsatisfactory adhesion to the back electrode layer, so that a primer must be employed. The use of primers, however, is costly, elaborate and ecologically dubious. With some embedding foils, for example the fast-crosslinking or so-called “fast-cure” EVA foil, even a primer does not lead to satisfactory adhesion.

Surprisingly, it has turned out that good adhesion of the back surface encapsulation material to the inventive contact layer is attained even without use of a primer, even with a fast-crosslinking embedding foil.

Due to the inventive tin-, copper- and/or silver-containing layer of the solar cell on the interface to the back surface encapsulation material, the contact strips can thus be fastened very well by soldering, on the one hand, and an excellent adhesion of the back surface encapsulation material to the back electrode layer is attained, on the other hand, preferably an adhesion corresponding to a tensile peel force of more than 5 N/cm, in particular more than 10 N/cm according to FINAT (peeling at 90° to the sample plane).

A primer can be completely omitted, even if the embedding foil on the interface with the tin-, copper- or silver-containing layer consists of a so-called “fast-cure” EVA foil, i.e. an EVA foil requiring for full crosslinking only a fraction of the process time of a conventional “standard-cure” EVA foil.

The embedding foil, i.e. in particular EVA, PVB, polyolefin or silicone foil, can be employed for laminating a further glass plate, so that when the substrate of the photovoltaic module consists of glass a glass/glass laminate arises, or for laminating one or more further plastic foils, so that when the substrate consists of glass a glass/foil laminate is formed, whereby said further foil or foils serve to protect the photovoltaic module from the atmosphere, i.e. as mechanical protection or protection from water vapor, light and the like.

The plastic foil can consist e.g. of a polycondensate, such as polyethylene terephthalate (PET), or a fluorine-containing hydrocarbon polymer, e.g. polyvinyl fluoride, which is distributed e.g. by the company DuPont under the trademark “Tedlar”.

The inventive solderable contact layer can at the same time serve as a protective layer for the reflector layer of the back electrode layer. In the event that silver, copper or other solderable materials or combinations of materials or alloys are employed for the reflector layer, there can occur during the soldering process a complete mixture (alloying) of the tin-solder with some or all layers of the back electrode layer and even up to the semiconductor. Further, this causes very high energy input into the semiconductor, the subjacent front electrode layer and the substrate. Instead of the tin-solder, other metal layers on the side of the metallic reflector layer facing away from the semiconductor layer can also alloy with the metallic reflector layer. This leads to a multiplicity of faults, such as short circuits, layer delaminations, substrate defects such as cracks, shelling, etc., and thus to an elevated proportion of rejects or modules of reduced quality.

The occurrence of soldering errors due to alloying of the layers of the back electrode layer up to the semiconductor layer, and the resulting high energy input into the semiconductor layer, the front electrode layer and the substrate can be countered according to the invention by a barrier layer consisting of a material alloying with the solder and/or the metallic reflector layer being provided between the contact layer and the metallic reflector layer.

Preferably, the barrier layer alloying with the solder consists of at least one layer of one of the metals: titanium, zircon, hafnium, aluminum, vanadium, tantalum, niobium, chromium, molybdenum, tungsten, manganese and iron, or an alloy of at least two of said metals, or an alloy of at least one of said metals with at least one further metal with one of said metals being the main component, based on weight. The thickness of the barrier layer is preferably at least 5 nm, in particular at least 10 nm.

The barrier layer not alloying with the metallic reflector layer preferably consists of an electrically conductive metal compound. The metal compound can be for example a carbide, silicide, nitride or boride. However, it is preferable to employ metal oxides for the barrier layer not alloying with the metallic reflector layer.

The metal oxides used are in particular metal oxides as also find use for the transparent front electrode layer. These are in particular doped zinc oxide or tin oxide, for example aluminum-doped zinc oxide, fluorine-doped tin oxide or indium tin oxide.

The thickness of the barrier layer consisting of the material not alloying with the reflector layer is preferably 2 to 500 nm, in particular 20 to 200 nm.

The barrier layer guarantees that, upon soldering, the layers of the back electrode layer do not alloy with the tin-solder and thus cause damage to the semiconductor as well as the front electrode layer or the substrate. An output loss of the module through the soldering process is thus prevented.

For production of the photovoltaic module, there are deposited on the trans-parent substrate the transparent front electrode layer, the semiconductor layer and the back electrode layer as functional layers, which are patterned by separating lines to form series-connected cells.

The metallic back electrode layer can be patterned with a laser whose light is absorbed by the semiconductor layer. Due to the laser beam the semiconductor material located in the laser focal point evaporates, causing the back electrode layer to be burned off in the area of the focal point. If the material of the back electrode layer is not burned off completely, however, and flakes and similar metallic material still adhere thereto, there can occur in the separating line between the back and front electrode layers short circuits and thus output losses of the module.

When the barrier layer not alloying with the metallic reflector layer consists of a metal compound, i.e. in particular a metal oxide, such as zinc oxide and/or tin oxide, however, the back electrode layer for laser patterning is given such brittleness that the energy input of the laser into the semiconductor layer of the module leads to complete burning off of the superjacent electrode layer. This prevents short circuits due to non-burned off flakes or similar parts consisting of metallic reflector layer material in the separating lines.

For patterning the back electrode layer it is preferable to employ a laser emitting laser light in the visible range, for example a neodymium-doped solid state laser, in particular a neodymium-doped yttrium vanadate laser (Nd:YVO₄ laser) or neodymium-doped yttrium aluminum garnet laser (Nd:YAG laser) with laser light of the second harmonic wavelength of 532 nm.

The patterning of the back electrode layer is preferably carried out in pulsed laser operation, for example with a Q switch. That is, the laser is preferably CW operated and Q-switched. The laser spots can be placed immediately next to each other with overlap. However, the laser patterning of the back electrode layer can be carried out example also with the third harmonic wavelength of 355 nm of the neodymium-doped solid state laser or with its fundamental wave of 1064 nm.

For example, it is possible to direct the laser radiation with a wavelength of 1064 nm through the transparent substrate onto the front electrode layer, which thereby heats up thermally in such a way that the superjacent semiconductor layer is thermally removed together with the back electrode layer and thus a patterning of the back electrode layer is effected.

Instead of neodymium-doped lasers it is also possible to use other lasers emitting in the infrared or visible range, for example ytterbium-doped lasers with a fundamental wavelength of 1070 nm, preferably with a frequency doubling or tripling of the fundamental wavelength.

Although additional separating lines are formed in the semiconductor layer upon patterning of the back electrode layer, they practically do not affect the output of the photovoltaic module.

For patterning the back electrode layer, the laser beam can be directed onto the back electrode layer directly. However, the patterning of the back electrode layer is preferably effected with a laser beam directed through the transparent substrate onto the semiconductor layer.

The coating of the semiconductor layer with the back electrode layer is preferably effected by sputtering.

In so doing, all sublayers of the back electrode layer can be applied to the semiconductor layer by sputtering, i.e. the metallic reflector layer, the barrier layer or barrier layers, any further layers up to the last contact layer terminating the back electrode layer on the far side of the semiconductor layer. Thus, the back electrode layer can be produced in a continuous process without any need to break the vacuum while sputtering.

Hereinafter the invention will be explained more closely by way of example with reference to the attached drawing. Therein are shown schematically:

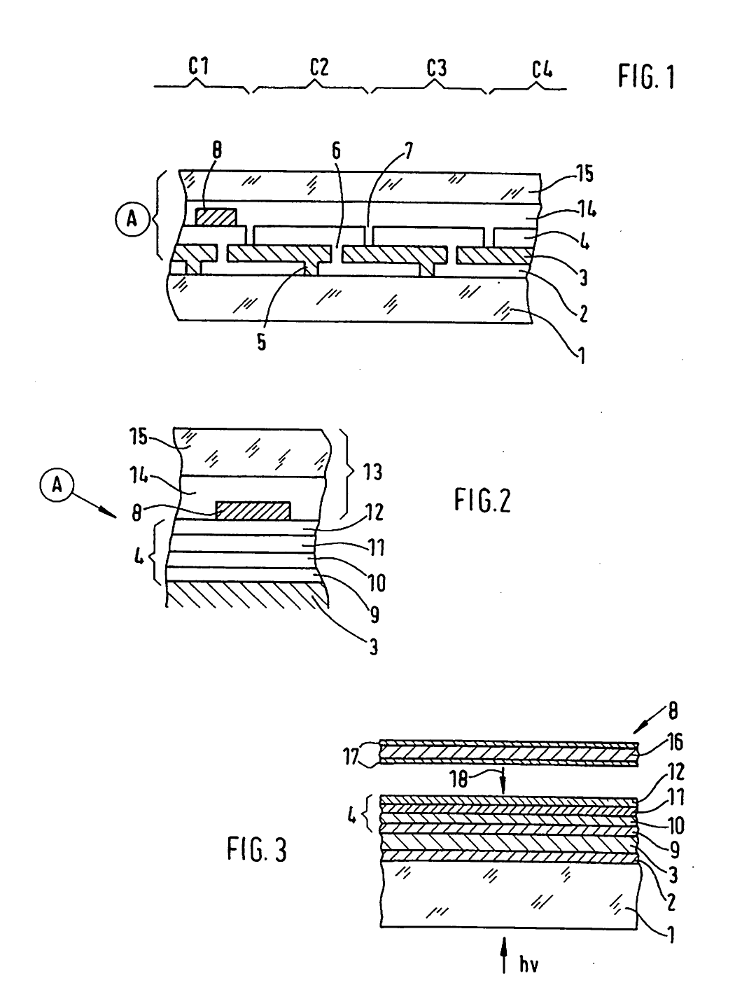

FIG. 1 a cross section through a part of a photovoltaic thin-film module;

FIG. 2 the layer structure on the semiconductor layer of the module according to FIG. 1 in an enlarged representation; and

FIG. 3 a longitudinal section through a solar cell of the photovoltaic module before fastening the contact strip by soldering;

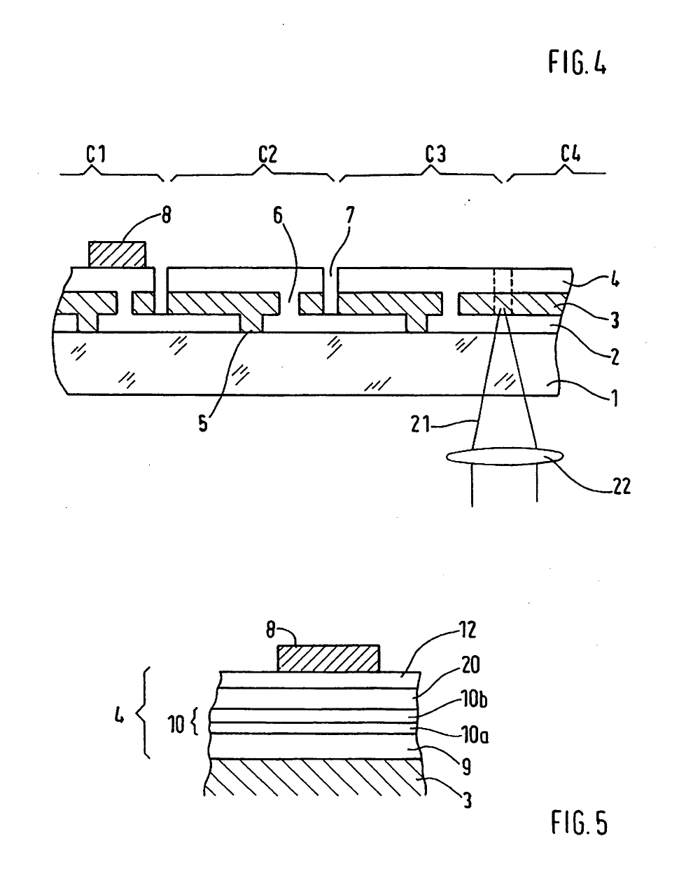

FIG. 4 a cross section through a part of a modified photovoltaic thin-film module; and

FIG. 5 a layer structure of the back electrode layer of the module according to FIG. 4 in an enlarged representation.

According to FIG. 1, a large-area transparent substrate 1, for example a glass plate, has provided thereon a front electrode layer 2, e.g. consisting of doped tin oxide, to which a semiconductor layer 3, e.g. consisting of amorphous silicon, is applied. The back electrode layer 4 is applied to the silicon semiconductor layer 3.

The module consists of single cells C1, C2, C3, C4 which are series-connected. For this purpose, the front electrode layer 2 is patterned by the separating lines 5, the silicon semiconductor layer 3 by the separating lines 6, and the back electrode layer 4 by the separating lines 7. The strip-shaped single cells C1, C2, C3, C4 extend perpendicularly to the current flow direction. The cell C1 is configured for current collection. For this purpose, a contact strip 8 is soldered to the back electrode layer 4 of the cell C1.

The back electrode layer 4 consists according to FIG. 2 of a metal oxide layer 9, e.g. of zinc oxide, facing the semiconductor layer 3, applied thereto a metal layer 10, e.g. of aluminum, copper, silver and/or chromium, which at the same time forms the reflector layer, a metallic barrier layer 11 consisting of a material not alloying with the solder 17 (FIG. 3), and the contact layer 12 consisting e.g. of oxidized tin.

The back electrode layer 4 has a back surface encapsulation material 13 laminated thereon. The back surface encapsulation material 13 consists of an embedding foil 14, for example an EVA, PVB, polyolefin or silicone embedding foil, with which a protective layer 15, e.g. a glass plate and/or one or more foils, e.g. consisting of PET, are laminated onto the photovoltaic module.

According to FIG. 3, the contact strip 8 which is to be fastened by soldered connection to the back electrode layer 4 of the solar cell 1 is formed by a metal strip 16, e.g. consisting of copper, which is coated with a solder 17 on both sides, i.e. on the joining surface facing the back electrode layer 4, and the opposing surface.

For soldering, the contact strip 8 is brought in contact with the contact layer 12 of the solar cell according to the arrow 18, whereby the contact strip 8 is heated inductively.

When the semiconductor layer 3 is formed by a crystalline semiconductor wafer, the back electrode layer has an accordingly changed structure.

The thin-film module according to FIG. 4 differs from that according to FIG. 1 substantially only in that the back surface encapsulation is omitted and the separating line 7 in the back electrode layer 4 also extends through the semiconductor layer 3.

The back electrode layer 4 consists according to FIG. 5 of a metal oxide layer 9, e.g. consisting of zinc oxide, facing the semiconductor layer 3, applied thereto a reflector layer 10, e.g. consisting of a silver sublayer 10a and an aluminum sublayer 10b, a brittle, electrically conductive layer 20, e.g. consisting of a metal oxide, for example zinc oxide, and a contact layer 12, e.g. consisting of oxidized tin or of copper, to which the contact strip 8 is soldered.

As shown in FIG. 4 on the right, for forming the separating line 7 in the back electrode layer 4 there is employed a laser whose laser beam 21 is focused with a lens 22 through the transparent substrate 1 and the front electrode layer 2 onto the semiconductor layer 3. The laser radiation, whose wavelength is in the spectral range of strong absorption of the semiconductor layer 3, for example at 532 nm, thus heats the semiconductor layer 3, in fact in such a way that it evaporates, or in any case is so heated that the superjacent back electrode layer 4 is burned off in this area and thus the separating line 7 formed. The separating line 7 in the back electrode layer 4 thus also extends into the semiconductor layer 3. However, this practically does not influence the output of the photovoltaic module.

The following examples will serve to explain the invention further.

### EXAMPLE 1

A contact strip consisting of a tinned copper strip is soldered to a photovoltaic module having a back electrode layer consisting of zinc oxide (layer thickness 90 nm), an aluminum layer (250 nm), a nickel vanadium layer (50 nm) to which a superficially oxidized tin (Sn) layer (20 nm) has been applied by sputtering. Subsequently a fast-cure EVA embedding foil is applied.

The tensile peel force for stripping the embedding foil from the photovoltaic module is ascertained by a FINAT test method (peel angle)90°, viz. by a damp heat test according to IEC 61646 but after an elevated time span of 2300 hours. Further, the solderability of the contact strip is ascertained.

### COMPARATIVE EXAMPLE 2

Example 1 was repeated except that the tin layer was omitted. Instead, a primer was applied before lamination.

### COMPARATIVE EXAMPLE 3

Comparative example 2 was repeated except that both the tin layer and the primer were omitted.

| | Terminating layer | Tensile peel force | Solderability |
|---|---|---|---|
| Ex. 1 | Sn without primer | 17 N/cm | yes |
| Comp. ex. 2 | NiV with primer | 1 N/cm | yes |
| Comp. ex. 3 | NiV without primer | 1 N/cm | yes |

### EXAMPLES 2 TO 4

There were employed thin-film solar cells that had been provided with a tin layer having a layer thickness of ≦7 nm, 20 nm and 35 nm by magnetron sputtering on the terminating nickel vanadium layer of the back electrode layer. Upon use of a contact strip with a coating consisting of an unleaded solder, the following peel values resulted after different soldering times:

Soldering time/s

| | | | | |
|---|---|---|---|---|
| Sn thickness | 0.7 s | 0.9 s | 1.1 s | 1.3 s |

Peel values

| | | | | | | | | | | |
|---|---|---|---|---|---|---|---|---|---|---|
| Ex. 2 | ≦7 | nm | <1 | N | <1 | N | <1 | N | <1 | N |
| Ex. 3 | 20 | nm | 5.5 | N | 6.3 | N | 7.4 | N | 8.4 | N |
| Ex. 4 | 35 | nm | 10.3 | N | 11.1 | N | 12.5 | N | 11.3 | N |

It can be seen that high peel values of the contact strip are obtained at a layer thickness of the tin layer of 20 or 35 nm, in fact even after a very short soldering time of 0.7 seconds at a layer thickness of 35 nm.

1. A photovoltaic module having a back electrode layer (4) to which contact strips (8) are fastened by a soldered connection, characterized in that the back electrode layer (4) is provided on its outer side facing the contact strips (8) with a tin-, copper- and/or silver-containing contact layer (12).

2. The photovoltaic module according to claim 1, characterized in that the layer thickness of the contact layer (12) is 1 to 500 nm.

3. The photovoltaic module according to claim 1 or 2, characterized in that the layer thickness of the contact layer (12) is 10 to 100 nm.

4. The photovoltaic module according to claim 1, characterized in that the tin-, copper- or silver-containing contact layer (12) consists of an alloy of said metals with at least one further metal.

5. The photovoltaic module according to claim 1, characterized in that the contact layer (12) is a tin-containing layer which consists of at least partly oxidized tin and/or an at least partly oxidized tin alloy.

6. The photovoltaic module according to claim 1, characterized in that the contact strips (8) are coated with a solder (17) having a layer thickness of 5 to 50 μm.

7. The photovoltaic module according to claim 1 or 6, characterized in that the solder (17) is tin-solder.

8. The photovoltaic module according to any of the above claims, characterized in that the back electrode layer (4) has a metallic reflector layer (10), and a barrier layer (11, 20) comprising a material not alloying with the solder (17) and/or the metallic reflector layer (10) is provided between the contact layer (12) and the metallic reflector layer (10).

9. The photovoltaic module according to claim 8, characterized in that the barrier layer (11) not alloying with the solder (17) is provided in the back electrode layer (4) on the side of the contact layer (12) facing away from the contact strip (8).

10. The photovoltaic module according to claim 8 or 9, characterized in that the barrier layer (11) not alloying with the solder (17) is a metallic barrier layer and consists of at least one layer of one of the metals: titanium, zircon, hafnium, aluminum, vanadium, tantalum, niobium, chromium, molybdenum, tungsten, manganese, iron, nickel and tellurium or an alloy consisting of at least two of said metals or an alloy of one of said metals with at least one further metal with one of said metals being the main component.

11. The photovoltaic module according to claim 10, characterized in that the thickness of the metallic barrier layer (11) is at least 5 nm.

12. The photovoltaic module according to claim 8, characterized in that the barrier layer (20) not alloying with the metallic reflector layer (10) consists of an electrically conductive metal compound.

13. The photovoltaic module according to claim 12, characterized in that the barrier layer (20) consisting of an electrically conductive metal compound has a thickness of 2 to 500 nm.

14. The photovoltaic module according to claim 12, characterized in that the electrically conductive metal compound is a metal oxide.

15. The photovoltaic module according to claim 14, characterized in that the metal oxide is a zinc oxide and/or tin oxide.

16. The photovoltaic module according to any of claims 8 to 15, characterized in that the metallic reflector layer (10) has a layer thickness of 50 to 500 nm.

17. The photovoltaic module according to any of claims 8 to 16, characterized in that
the metallic reflector layer (10) consists of at least one layer (11, 12) consisting of silver, aluminum, copper and/or chromium or an alloy of said metals.

18. The photovoltaic module according to any of the above claims, characterized in that it has a back surface encapsulation material (13) which covers the back electrode layer (4) having the contact strips (8).

19. The photovoltaic module according to claim 1, characterized in that the back surface encapsulation material (13) is formed from an embedding foil (14) at least on the interface with the contact layer (12).

20. The photovoltaic module according to claim 19, characterized in that the embedding foil (14) is a foil consisting of EVA (ethyl vinyl acetate), PVB (polyvinyl butyral), polyolefin or silicone.

21. The photovoltaic module according to claim 19 or 20, characterized in that the back surface encapsulation material (13) has apart from the embedding foil (14) a protective layer (15) which is disposed on the side of the embedding foil (14) opposing the back electrode layer.

22. The photovoltaic module according to claim 21, characterized in that the protective layer (15) consists of glass and/or at least one plastic foil.

23. The photovoltaic module according to claim 22, characterized in that the plastic foil consists of a polycondensate or a fluorine-containing hydrocarbon polymer.

24. A method for fastening the contact strips (8) to the back electrode layer (4) of a photovoltaic module by a soldered connection, characterized in that the back electrode layer (4) is provided on its outer side with a tin-, copper- and/or silver-containing contact layer (12), and the contact strip (8) provided with solder (17) at least on the joining surface is connected to the contact layer (12) by soldering.

25. The method according to claim 24, characterized in that the contact layer (12) and/or the barrier layer (11) is deposited by physical gas phase deposition.

26. The method according to claim 25, characterized in that the physical gas phase deposition method applied is magnetron sputtering.

27. The method according to claim 24, characterized in that an inductive soldering method is employed.

28. The method according to claim 24 or 27, characterized in that a contact strip (8) is employed which is provided at least on the joining surface with a solder (17) having a layer thickness of 5 to 50 μm.

29. The method according to claim 24 or 28, characterized in that a contact strip (8) provided with an unleaded solder (17) is employed.
